(19) United States
(12) Patent Application Publication
(10) Pub. No.: US 2010/0173228 A1
(43) Pub. Date: Jul. 8, 2010

(54) Nanotube and Carbon Layer Nanostructured Composites

(75) Inventors: Gordon George Wallace, Wollongong (AU); Ju Chen, Wollongong (AU); Andrew Ian Minett, Wollongong (AU)

Correspondence Address: Ballard Spahr LLP, SUITE 1000, 999 PEACHTREE STREET, ATLANTA, GA, 30309-3915, US

(73) Assignee: University of Wollongong, Wollongong (AU)

(21) Appl. No.: 12/519,091

(22) PCT Filed: Dec. 14, 2007
(86) PCT No.: PCT/AU07/01933

§ 371 Date: Jan. 14, 2010

(30) Foreign Application Priority Data
Dec. 14, 2006 (AU) AU 2006907002

(51) Int. Cl. H01M 4/02; C23C 16/44; C23C 16/26; C23C 16/01; B32B 9/04; C25B 11/12; B82B 1/00; G01N 7/00

(52) U.S. Cl. 429/532; 427/249.1; 264/81; 428/408; 429/209; 204/290.15; 422/186; 96/15; 73/23.2; 977/742; 977/752; 977/734; 977/902

(57) ABSTRACT

The present invention relates to nanostructured composites comprising a nanotube network which is at least partially embedded within a carbon layer. The present invention particularly relates to conducting nanostructured composites for use in the fields of energy conversion, energy storage and also the biomedical field. The present invention also relates to a process via CVD of carbon onto a catalyst layer on a substrate. This abstract is intended as a scanning tool for purposes of searching in the particular art and is not intended to be limiting of the present invention.

### FIELD

The present invention relates to nanostructured composites, particularly conducting nanostructured composites for use in the fields of energy conversion, energy storage and also the biomedical field. The present invention also relates to a process for preparing the nanostructured composites.

### BACKGROUND

As non-renewable fuel source diminish, the need for more efficient methods of energy conversion and storage is becoming paramount. Common energy storage devices such as batteries and capacitors rely on electrodes to function.

Electrodes for photochemical cells require a high surface area to enable efficient charge transfer to the electrolyte. Electrodes to be used in devices for charge storage also require a high surface area and high conductivity.

Bio-electrodes are used to deliver charge to, or sense electric pulses on or within living organisms. Common bio-electrodes include pacemaker electrodes and electrocardiogram (ECG) pads. The interaction between an electrode and a living organism is essential to its long term use. An electrode must be biocompatible, so that it is not toxic to the living organism in which it is implanted.

Commercial implantable bio-electrodes for humans are made from Pt and Pt—Ir alloys. Often these metals are coated with titanium nitride or conducting oxides (e.g. RuO₂ or IrO₂) to increase their surface area, or adjust their bio-interaction.

Nanotubes, for example carbon nanotubes, present new materials for the construction of electrodes for electrochemical devices. Such electrodes require high conductivity, strength and surface area. The latter two requirements are often incompatible. Electrodes composed entirely of carbon nanotubes (bucky paper) have high surface areas but are typically weak, nonflexible, and have insufficient conductivity for practical macroscopic applications.

There has been much investigation into the manufacture of carbon nanotubes for instance, carbon nanotube platforms have been manufactured via the formation of aligned carbon nanotube arrays. The large scale synthesis of vertically aligned CNTs was first reported by Li et al¹, who described the large scale synthesis of aligned carbon nanotubes using a method based on chemical vapour deposition catalysed by iron nanoparticles embedded in mesoporous silica.

Techniques for manufacturing vertically aligned carbon nanotube forests and arrays fabricated on catalyst printed planar substrates by chemical vapour deposition require deposition and patterning, usually in separate processing steps, of catalyst material, typically in nanoparticle assemblies or thin film forms. This complicates the nanotube fabrication method.^{2,3}

Also, to date, growth of carbon nanotube forests and/or other types of nanotube forests have required to be established on non-conducting substrates. Therefore, these aligned forests need to be transferred to a conducting substrate⁴, or require metal deposited contacts⁵ to be post-processed on top of the forest before they are suitable as electrode materials for integration into devices.

Usually, the process of chemical vapour deposition produces nanotubes in which the nanotubes are not connected to the substrate, rather, they just lie on the substrate, and therefore any connection to the substrate is not mechanically or electrically robust.

There is a need to develop simple methods of making nanostructured composites. These nanostructured composites are required to be mechanically robust and preferably with sufficient conductivity for use in applications such as electrodes for energy storage and conversion.

### SUMMARY

The present invention provides a nanostructured composite comprising a nanotube network integrated within a carbon layer.

By “intergrated within” we mean at least partially embedded in the carbon layer.

In one embodiment, the composite is conducting. Preferably the carbon layer is highly conducting, such as, an activated carbon layer (CL), for example, an amorphous carbon (AC) layer. This embodiment is particularly useful for energy conversion and storage.

The nanostructured composite may further comprise a substrate, thus providing a nanostructured composite substrate structure.

Preferably, the carbon layer is attached to the substrate. By “attached”, we mean physically retained by the substrate.

In one embodiment, the substrate is a metal, resulting in a nanostructured composite substrate structure having metal-like conducting properties.

In one embodiment, the composite is biocompatible resulting in a biomaterial composite. The nanotubes and/or the carbon layer may be biocompatible. Where the composite further comprises a substrate, the nanotubes, carbon layer and/or the substrate may be biocompatible.

The present invention further provides a process for preparing a nanostructured composite or a nanostructured composite substrate structure which comprises the steps of:
i) Depositing a metal catalyst on a substrate;
ii) chemical vapour deposition (CVD) growth of a nanotube network with a carbon layer underneath from the catalyst on the substrate to form a nanostructured composite substrate structure; and
iii) optionally separating the nanostructured composite from the substrate.

The nanotubes are orientated in the nanostructured composite such that they protrude from the carbon layer. The nanotubes are partially embedded in the carbon layer, that is, the starting growth point of the nanotube is embedded in the carbon layer and the remaining portion of the nanotube protrudes from the carbon layer. In other words the nanotubes grow from the metal nanoparticles formed by reduction of the organic metal catalyst which is embedded in the carbon layer to form intimate connection between the nanotubes and the carbon layer.

In one embodiment the substrate of step ii) is in the form of a dispersing media, optionally comprising a biomolecule, the dispersing media being cast onto the nanotube layer.

The present invention further provides an article comprised wholly or partly of the nanostructured composite and/or the nanostructured composite substrate structure described above. Preferably, the article is electrically conducting and examples include electrodes for energy storage and conversion, such as capacitors, hybrid battery capacitors, supercapacitors and batteries; electrodes for use as fuel cells, gas storage mediums and sensors; and electrodes for use in the biomedical field such as bioelectrodes, biofuel cells and substrates for electrically stimulated bio-growth.

### DETAILED DESCRIPTION

### Nanostructued Composite

Composites are generally described as materials made from two or more constituent materials which remain separate and distinct within the finished structure. Usually the constituent materials are of two types, generally described as matrix and reinforcement materials. It is generally understood that the matrix material surrounds and supports the reinforcement material and a type of synergism is achieved that produces a material with enhanced properties.

In the present invention, nanostructured composites are provided in which the nanotubes are viewed as the matrix material, and the carbon layer, to which they are attached, is viewed as the reinforcement of the composite. In this arrangement a more robust material is provided compared with (for example) electrodes composed entirely of carbon nanotubes (bucky paper).

Nanotubes are typically small cylinders made of organic or inorganic materials. Known types of nanotubes include carbon nanotubes, inorganic nanotubes and peptidyl nanotubes. Inorganic nanotubes include WS₂ and metal oxide nanotubes such as oxides of titanium and molybdenum. Preferably the nanotubes are carbon nanotubes (CNTs).

CNTs are sheets of graphite that have been rolled up into cylindrical tubes. The basic repeating unit of the graphite sheet consists of hexagonal rings of carbon atoms, with a carbon-carbon bond length of about 1.45 Å. Depending on how they are made, the nanotubes may be single-walled nanotubes (SWNTs), double walled carbon nanotubes (DWNTs) and/or multi-walled nanotubes (MWNTs). A typical SWNT has a diameter of about 0.7 to 1.4 nm.

The structural characteristics of nanotubes provide them with unique physical properties.

Nanotubes may have up to 100 times the mechanical strength of steel and can be up to several mm in length. They exhibit the electrical characteristics of either metals or semiconductors, depending on the degree of chirality or twist of the nanotube. Different forms of nanotubes are known as armchair, zigzag and chiral nanotubes. The electronic properties of carbon nanotubes are determined in part by the diameter and therefore the ‘form’ of the nanotube.

The spaces between the graphite layers of carbon nanotubes, local disorders arising from defective structures and the central core should permit large insertion capacity. Due to their characteristics of high stability, low mass density, low resistance, high accessible surface area and narrow pore size distribution, carbon nanotubes are suitable materials for electrochemical capacitors.

The nanotubes are oriented in the composite of the present invention such that they protrude from the carbon layer. The nanotubes are partially embedded in the carbon layer, that is, a portion of one end of the nanotube is embedded in the carbon layer and the remaining portion of the nanotube protrudes from the carbon layer. In other words the nanotubes grow from the metal nanoparticles formed by reduction of the organic metal catalyst which is embedded in the carbon layer to form intimate connection between the nanotubes and the carbon layer. The nanocomposite is prepared via a process involving a metal catalyst deposited on a substrate. In the process, the metal nanoparticles of the catalyst become embedded in the carbon layer and it may be said that the nanotubes grow from these metal nanoparticles, resulting in intimate connection between the nanotubes and the carbon layer.

The nanotubes of the nanocomposite are preferably unaligned nanotubes which are capable of forming three-dimensional entangled networks. The nanotubes may be single-walled nanotubes (SWNTs), double-walled nanotubes (DWNTs) and/or multi-walled nanotubes (MWNTs). Preferably the nanotubes are unaligned, multi-walled nanotubes, typically termed: an unaligned, multiwall nanotube networks or forests.

The nanotubes are preferably unaligned multi-wall carbon nanotubes (MWNTS) of an average length greater than 1 μm, preferably greater than 50 μm, more preferably greater than 100 μm, and an external diameter of 10-100 nm, preferably 20-40 nm.

Aligned carbon nanotubes are highly ordered and considered to have good electrochemical properties. However, the composites containing unaligned nanotubes also show good electrochemical properties, in some circumstances superior to vertically aligned nanotubes grown in the same furnace.

As stated above, the nanotubes are oriented in the nanocomposite such that they protrude from the carbon layer. The carbon layer is preferably conducting and in such an embodiment, the conducting carbon layer means the previous requirement of depositing metal contacts on the nanotubes to obtain a conducting material is avoided. Growth of the nanotubes from the carbon layer itself results in the nanotubes being integrated within the carbon layer.

The carbon layer is preferably an activated carbon layer (CL) such as an amorphous carbon (AC) layer, more preferably a non-graphitised carbon layer.

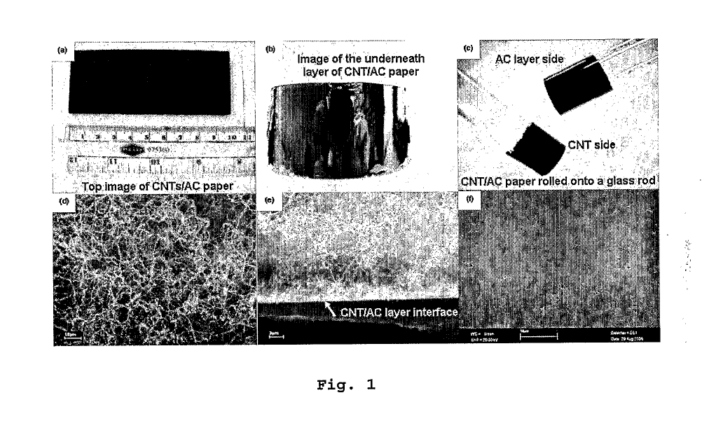

In one embodiment, the carbon layer is less than 10 μm, preferably less than 5 μm, more preferably less than 1 μm in thickness. SEM imaging (see FIG. 1) shows a uniformly dense continuous AC film with nano-sized porosity. XRD spectra shows the AC layer to be disordered, but activated, AC.

The carbon layer may contain a metal or combination of metals originating from the metal catalyst utilized in the process of preparing a composite. The metal originating from the metal catalyst may be a transition metal such as palladium, iron, rhodium, nickel, molybdenum and/or cobalt, preferably iron, nickel or cobalt.

The metal content of the carbon layer may be less than 20%, preferably less than 10%, more preferably less than 5% (obtained from Energy Dispersive X-Ray Analysis). At such a small concentration, the metal content alone could not be considered to be responsible for the conductivity of the carbon layer.

Preferably, the composite is flexible and robust. The carbon layer adds strength to the composite yet maintains sufficient flexibility to enable it to be shaped for a variety of uses. The composite can be of varying thickness. Preferably, the thickness of the composite is 1-100 μm, more preferably 5-50 μm, most preferably about 20 μm making it suitable for use in flexible thin supercapacitors and as anode materials for batteries such as Li-ion rechargeable batteries.

The composite may further comprise a substrate, thus providing a nanostructured composite substrate structure.

A substrate is utilised in the preparation of the nanocomposite of the present invention. It provides the surface onto which the catalyst film is prepared and from which the nanotube network with a carbon layer underneath are grown. Growth of nanotubes requires high temperatures, usually of the order of around 500° C. and greater. This step can be achieved using CVD involving a substrate capable of withstanding the high temperatures required for nanotube growth in an inert atmosphere, for example, Ar or N₂ gas. The substrate can be conducting or non-conducting.

Suitable examples of conducting substrates include glassy carbon; metals or metal foils, for example, copper, iron, nickel, platinum and aluminium metals or metal foils; metal coated quartz plates and glassy slides; carbon paper such as carbon fiber paper; carbon; carbon nanotube fibre; and carbon nanotube paper.

Suitable examples of non-conducting substrates include quartz, silicon wafers, glassy slides and inorganic composites, for example metal oxide films.

Alternatively, the nanocomposite is separated from the substrate on which it is prepared and utilized alone. In this alternative arrangement, the composite may be transferred to another substrate with properties suited to a desired application. The substrate may be chosen from those listed above, or can be chosen from any other substrates, not necessarily capable of withstanding the high temperatures required for nanotube growth, such as non-polymeric materials for example metals and polymeric materials.

In one embodiment, the use of a metal substrate results in a composite substrate structure having metal-like conducting properties.

Suitable examples of metal substrates include platinum, metal foils for example copper foils for use in rechargeable batteries and aluminium foils for use in capacitors, metal-coated membranes, metal coated textiles and metal coated polymers fibres.

The polymeric substrates may include Poly(styrene-β-isobutylene-β-styrene) (SIBS) which is a soft, elastomeric triblock copolymer that is an effective biomaterial due to its superior biostability and biocompatibility. Other polymeric substrates include electronic conductors such as polyethylene dioxythiophene (PEDOT), soluble pyrroles, polythiophenes and/or polyanilines; acrylate polymers; acrylic acid polymers; polyacrylic esters; polyacrylamides; polyacrylonitriles; chlorinated polymers; fluorinated polymers; styrenic polymers; polyurethanes; natural rubber; synthetic rubber polymers; vinylchloride-acrylate polymers; and copolymers thereof. Specific examples of polymeric substrates, include, but are not limited to, poly(vinyl acetate), poly(acrylic acid), poly(methyl methacrylate), polyacrylamide, polyacrylonitrile, polyvinylpropionate, polystyrene, polytetrafluoroethylene, poly(vinyl chloride), poly(vinylidene chloride), poly(vinyl chloride-ethylene), poly(vinyl chloride-propylene), poly(styrene-co-butadiene), styrene-acrylate copolymers, ethylene-vinyl chloride copolymer, poly(vinyl acetate-acrylate), poly(vinyl acetate-ethylene) and combinations thereof.

In another embodiment, the nanotubes, carbon layer and/or substrate can be chemically modified, for example by attaching biomolecules, catalysts and/or additional conductors.

When biomolecules are attached, a biocompatible composite and/or substrate structure is produced which may function as a biomaterial.

The term “biomolecule” generally refers to molecules or polymers of the type found within living organisms or cells and chemical compounds interacting with such molecules. Examples include biological polyelectrolytes such as hyaluronic acid (HA), chitosan, heparin, chondroitin sulphate, polyglycolic acid (PGA), polylactic acid (PLA), polyamides, poly-2-hydroxy-butyrate (PHB), polycaprolactone (PCL), poly(lactic-co-glycolic)acid (PLGA), protamine sulfate, polyallylamine, polydiallyldimethylammonium, polyethyleneimine, eudragit, gelatin, spermidine, albumin, polyacrylic acid, sodium alginate, polystyrene sulfonate, carrageenin, carboxymethylcellulose; nucleic acids such as DNA, cDNA, RNA, oligonucleotide, oligoribonucleotide, modified oligonucleotide, modified oligoribonucleotide and peptide nucleic acid (PNA) or hybrid molecules thereof; polyaminoacids such as poly-L-lysine, poly-L-arginine, poly-L-aspartic acid, poly-D-glutamaic acid, poly-L-glutamaic acid, poly-L-histidine and poly-(DL)-lactide; proteins such as growth factor receptors, catecholamine receptors, amino acid derivative receptors, cytokine receptors, lectins, cytokines and transcription factors; enzymes such as proteases, kinases, phosphatases, GTPases and hydrolases; polysaccharides such as cellulose, amylose and glycogen; lipids such as chylomicron and glycolipid; and hormones such as amino-derived hormones, peptide hormones and steroid hormones.

Polyelectrolytes are polymers having ionically dissociable groups, which can be a component or substituent of the polymer chain. Usually, the number of these ionically dissociable groups in the polyelectrolytes is so large that the polymers in dissociated form (also called polyions) are water-soluble. Depending on the type of dissociable groups, polyelectrolytes are typically classified as polyacids and polybases. When dissociated, polyacids form polyanions, with protons being split off, which can be inorganic, organic and biopolymers. Polybases contain groups which are capable of accepting protons, e.g., by reaction with acids, with a salt being formed.

The structures of some biomolecules suitable for use in the composite and composite substrate structure of the present invention are set out below:

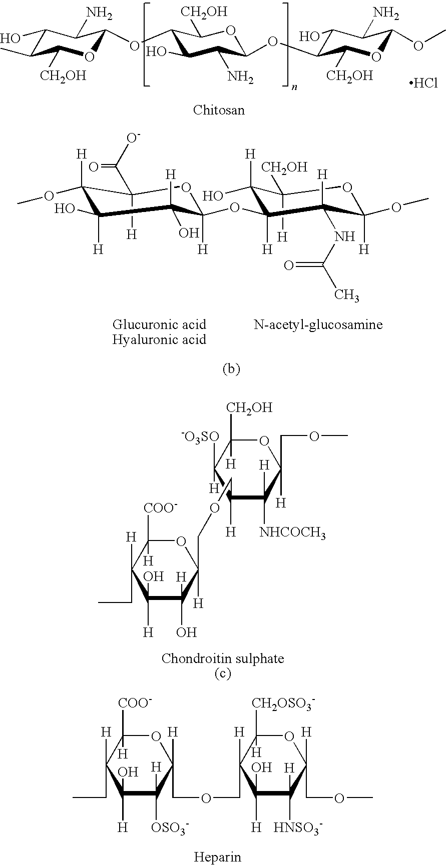

It will be appreciated that the biomolecule may include functional groups to allow further control of the biointeraction such as biomolecules which convey active ingredients for example drugs, hormones, growth factors or antibiotics. The biomolecule can also be chosen depending on the desired application, for example, if the composite was to be used to promote or inhibit adhesion of certain cell types it may be advantageous to use biomolecules which promote nerve or endothelial cell growth or inhibit smooth muscle cell growth (fibroblasts).

The biomolecule can include a monomer for example pyrrole and/or an oxidant, for example FeCl₃. In such embodiments, biomolecule can be rendered conductive by subsequent electrochemical or chemical oxidation if one or more monomers are present, or by vapour phase polymerisation if one or more oxidants are present in the substrate.

More than one biomolecule may be present in the nanocomposite and/or substrate of the present invention. The choice of the biomolecule will be determined by the end use of the composite or composite substrate structure.

The nanotube surface may also be modified with an additional conductor such as metals by sputter coating or electrodeposition, or a conducting polymer by solution chemical or vapour phase polymerisation or by electrodeposition.

### Process

The process for preparing the nanostructured composite or a nanostructured composite substrate structure includes the steps of:
i) depositing a metal catalyst on a substrate;
ii) chemical vapour deposition (CVD) growth of a nanotube network with a carbon layer underneath from the catalyst on the substrate to form a nanostructured composite substrate structure; and
iii) optionally separating the nanostructured composite from the substrate.

The first step involves depositing a metal catalyst film on a substrate. The substrate provides the surface onto which a catalyst film is prepared, from which the nanotubes are grown, and on which the carbon layer is formed.

The catalyst can be any catalyst suitable for catalysing nanotube growth.

The metal catalyst may be an organic metal catalyst or an inorganic metal catalyst, preferably an organic metal salt catalyst.

A organic metal catalyst includes a metal-carbon bond. The carbon of this metal-carbon bond is nucleophilic and capable of giving rise to a carbon-carbon bond. It is hypothesised that this initiates the growth of nanotubes, in particular carbon nanotubes.

The metal of the metal catalyst can be a transition metal such as palladium, iron, thodium, nickel, molybdenum and cobalt, preferably iron, nickel or cobalt.

Suitable organic salts include optionally substituted aryl or heteroaryl sulfonates for example, toluenesulfonate, alkyl benzene sulfonates and pyridinesulfonates; and carboxylic acid salts such as acetates or acetylacetonates.

Specific examples of organic metal salt catalysts as are as follows:
iron (III) p-toluenesulfonate (Fe(III)pTS)

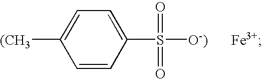

iron (III) dodecylbenzenesulfonate (Fe(III)DBS)

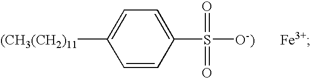

iron (III) pyridinesulfonate (Fe(III)PS)

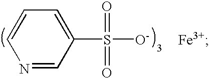

iron (III) camphor sulfonic acid;
nickel (II) acetate;
nickel (II) acetylacetonate;
cobalt (II) acetate; and
cobalt (II) acetylacetonate.

The catalyst film can be prepared by dissolving a metal salt with an organic compound in a solvent and depositing this on a substrate. For example, a catalyst film can be prepared by mixing FeCl₃ with NaCSA in a molar ratio of 1:1, in an organic solvent, for example ethanol. Alternatively, the catalyst can be directly deposited on the substrate from organic solvents, such as ethanol. The organic solvent can then be removed prior to the second step by annealing.

The catalyst film can be deposited using any suitable known technique, such as, spin coating. Preferably the catalyst forms a stable, thin film on the substrate. The film may be of suitable thickness to catalyse growth of nanotubes. Preferably the catalyst film is <50 μm, more preferably <10 μm in thickness.

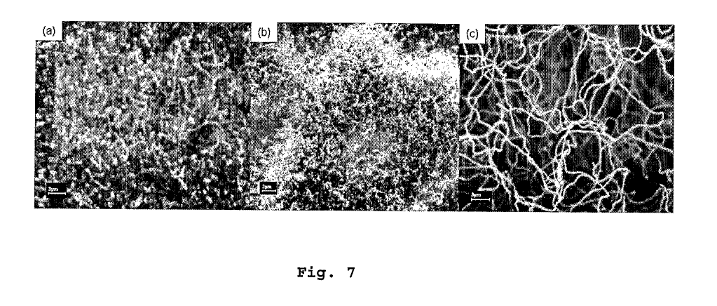

The use of different catalysts can influence the growth of the nanotubes resulting in a variety of different nanotube lengths and diameters. The choice of catalyst can also impact on the porosity of the nanotubes. For example, FIG. 7 shows that carbon nanotubes grown from Fe(III)DBS (see FIG. 7a) have shorter but larger diameter nanotubes when compared with those grown from Fe(III)PS (see FIG. 7b) and the Fe(III)pTS (see FIG. 7c). The trend D_{DBS}>D_{PS}>D_{pTS} (D=diameter) and L_{DBS}<L_{PS}<L_{pTS} (L=length) may be attributed to the different properties of Fe(III) organic moieties.

The metal catalyst which provided the highest quality carbon nanotubes with the greatest porosity carbon nanotube forest were grown from Fe(III)pTS.

The sheet resistances of the resulting carbon layer of the nanocomposite were also influenced by choice of catalyst. For example, the sheet resistances were found to be 46Ω, 86Ω, 65Ω and 57Ω per square for the Fe (III) pTS, Fe(III)DBS, Fe(III)PS and Fe(III)CSA respectively. Accordingly, Fe(III)PTS is the most preferred catalyst as it produces most conductive composites.

The second step of the preparation of the nanocomposite involves CVD growth of the nanotube network with the carbon layer underneath from the catalyst film on the substrate. In this step, a carbon source is utilized, preferably a gaseous carbon source. It has been noted that in the absence of a carbon source, the resistance of the carbon layer is found to be approximately 5 kΩ. Addition of a carbon source to the growth step lowers the resistance of the carbon layer by a factor of greater than 100, thus making it much more conductive.

Examples of carbon sources include alkanes, alkenes, alkynes and/or aryls and derivatives thereof. Suitable examples of alkanes are methane, ethane, propane, isopropane, butane, isobutane, sec-butane, tert-butane, pentane, neopentane, hexane and the like. Suitable examples of alkenes are ethylene, propene, 1-butene, 2-butene, 2-methyl propene, 3,3-dimethyl-1-butene, 4-methyl-2-pentene, 1,3-butadiene, 2-methyl-1,3-butadiene, isoprene, (2E,4E)-2,4-hexadiene, cyclopentene, cyclohexene, 1,2-dimethylcyclopentene, 5-methyl-1,3-cyclohexadiene and the like. Suitable examples of alkynes are: acetylene, propyne, 1-butyne, 2-butyne, 3-methyl-1-butyne, 1-pentyne, 2-pentyne, 1-hexyne, 2-hexyne, 3-hexyne, 3,3-dimethyl-1-butyne, 1-octyne, 1-nonyne, 1-decyne and the like. Suitable examples of aryls include phenyl, naphthyl, tetrahydronaphthyl, indane and biphenyl. Preferably, the carbon source is methane, ethylene and/or acetylene.

Preferably, the CVD is initially carried out at 500° C. under Ar/H₂ gas flow to reduce the metal catalyst to metal nanoparticles. The growth phase then follows which is preferably carried out at 800° C.

In a preferred embodiment, the preparation of the composite utilises an organic ferric salt as a catalyst and acetylene as a carbon source. Even further preferably, it utilizes Fe(III) pTS as the catalyst and acetylene as the carbon source.

If desired, the composite can be optionally removed from the substrate. The composite could then be transferred to another substrate with properties suited to a desired application. Alternatively polymer or metal films can be deposited and cured on top of the nanotube layer prior to removal from the substrate.

### Uses/Applications

The composites and composite substrate structures of the present invention are suitable for a variety of applications. In particular, the embodiment in which the nanocomposite is conducting makes it suitable for use in the fields of energy conversion and storage and in materials and devices that require conducting high surface area materials, such as electrodes for capacitors, hybrid battery/capacitors, supercapacitors, batteries, fuel cells, electrocatalysts, gas storage mediums, sensors, actuators, electromechanical actuators, photoelectrochemical solarcells and/or bioelectodes for electrical stimulation of cells and tissue.

Composites of entangled carbon nanotubes and AC on copper foil substrates are suitable for use in rechargeable batteries.

Composites of entangled carbon nanotubes and AC on aluminum foil substrates are suitable for use in capacitors.

Composites of entangled carbon nanotubes and AC on carbon paper substrates are suitable for use in fuel cells.

Composites of entangled carbon nanotubes and AC on membranes substrates are suitable for use in actuators.

The composites may be biocompatible and together with their conducting properties make them suitable for medical applications that require electrostimulation, the passage of an electrical current or electrical sensing such as bio-electrodes, biofuel cells or as substrates for electrically stimulated bio-growth.

The composites exhibit sufficient conductivity, electrochemical capacitance and mechanical properties to be used directly as electrodes implanted into living organisms for the purpose of electrical sensing and stimulation. Specific applications include pacemaker electrodes, ECG pads, biosensors, muscle stimulation, epilepsy control and electrical stimulated cell regrowth.

Electrodes for biological implants typically consist of platinum or iridium and their derivatives. Embodiments of the present invention provide electrically conducting nanocomposites that may contain biomolecules. Biomolecules such as chitosan are currently used in conjunction with many implants in the human body. Furthermore, functional groups may be added to chitosan to allow further control of the bio-interaction. The bio-compatibility of carbon nanotubes is not known, however initial studies show great promise. Therefore, potentially a new bio-electrode which is robust and efficient may be produced. These bio-electrodes should also be efficient and robust.

### DETAILED DESCRIPTION OF FIGURES

In the examples which follow, reference will be made to the accompanying drawings in which:

FIG. 1. Several Scanning Electron Micrograph (SEM) and optical images of free standing CNT/AC paper; (a) digital image of the upper surface of the CNT/AC, after CVD growth on a 40 cm2 quartz plate; (b) digital image of the underneath surface of the AC layer when removed from the substrate. The reflectivity of the layer is visible from the reflected image of the photographer easily observed in the image; (c) digital image of CNT/AC paper removed from the quartz substrate and rolled onto glass rods, indicating the flexibility and mechanical robustness of both sides of the CNT/AC composite paper. (d) SEM image of the top surface of the film, showing a dense entanglement of carbon nanotubes; (e) SEM image of the cross section of the CNT/AC paper; showing an obvious ‘intersection’ between the AC layer (indicated by the white arrow) and the upper carbon nanotube network layer; and (f) SEM image of the underneath of the AC layer, showing densely packed but still porous morphology.

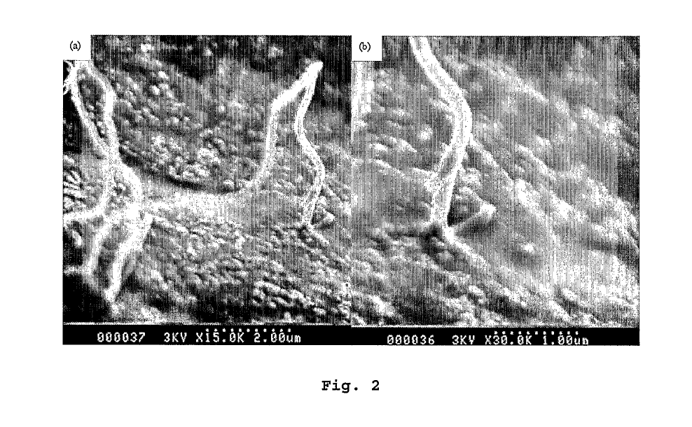

FIG. 2. High resolution scanning electron microscopy images of the CNT-AC intersection region, showing intimate contact between the outer nanotube shell and the amorphous carbon layer (left image). Right image is a higher magnification image of one region in the left image, which suggests that the CNT is growing out through the AC layer and not merely on top of it.

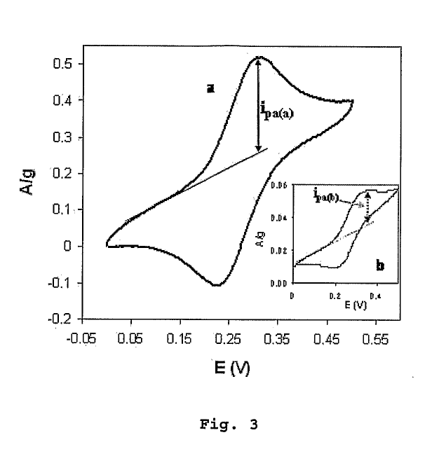

FIG. 3. Cyclic voltammograms performed in a conventional three-electrode cell where the working electrode was: (a) CNT/AC paper and (b) commercial MWCNT mat (NanoLab, Boston) in aqueous 1 mM K4Fe(CN)6/1.0 M NaNO3 under identical experimental conditions. The y-axis is displayed as Amps/g so direct comparison between the two different morphologies can be made. Scan rate: 5 mV s−1.

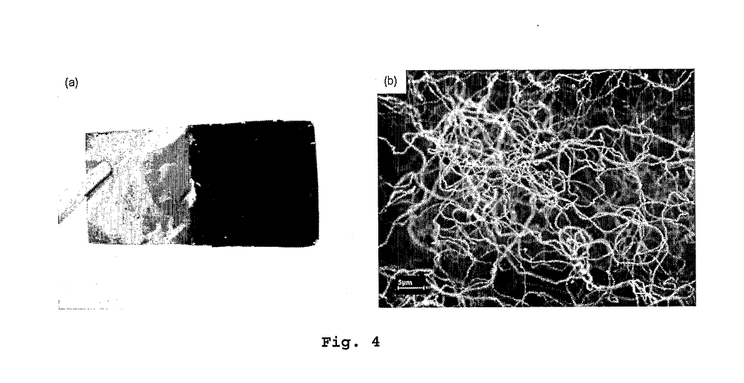

FIG. 4. Digital and SEM images of free-standing CNT/AC/metal paper, (a) digital image of CNT/AC on copper foil, (b) SEM image of CNT layer on copper foil.

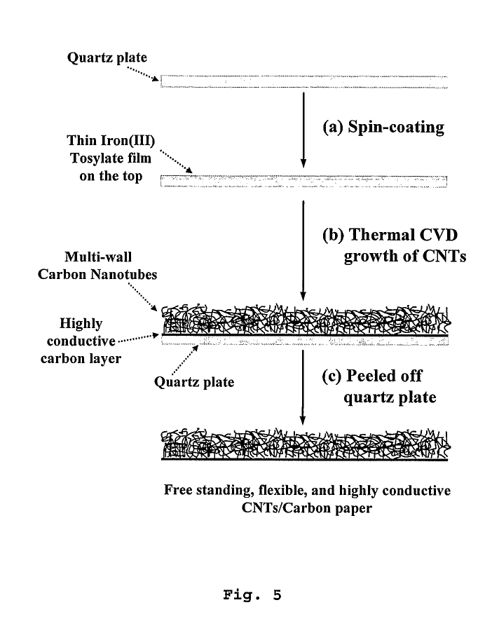

FIG. 5. Schematic illustration of a procedure for the preparation of CNT/AC paper in accordance with an embodiment of the invention: (a) spin-coating a thin Fe(III) pTS film (1 to 5 μm) onto cleaned quartz plate; (b) thermal CVD growth of multi-wall carbon nanotubes with a highly conductive carbon layer underneath using acetylene as carbon source; (c) free-standing paper peeled off from quartz plate.

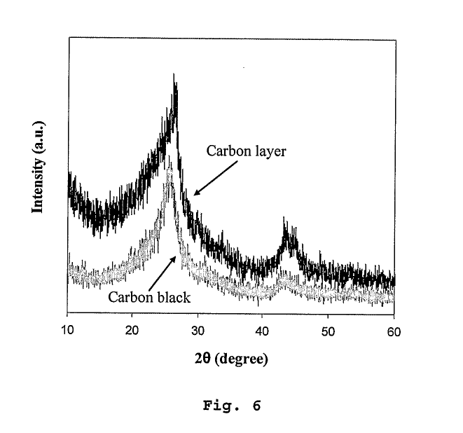

FIG. 6. XRD response for the underneath AC layer and comparison with a conventional Carbon Black sample.

FIG. 7. Scanning Electron Microscope images of the top surface of free standing CNT/AC papers grown from; (a) Fe(III) DBS, (b) Fe(III)PS, and (c) Fe(III) pTS. Images are shown at the same magnification.

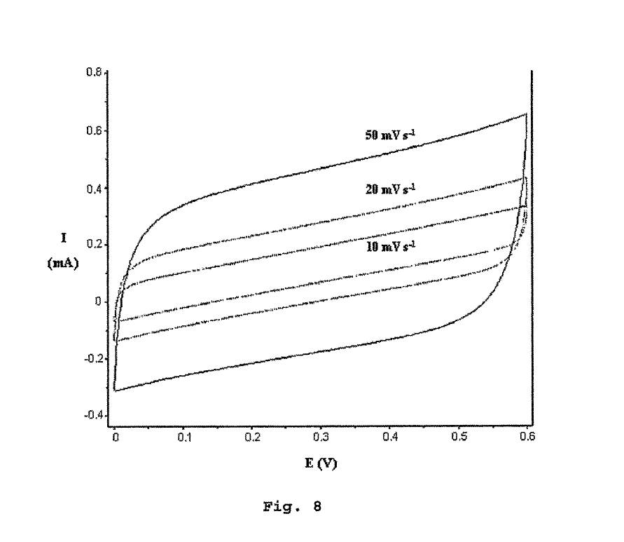

FIG. 8. Overlay of cyclic voltammograms obtained using a free-standing CNT/AC paper as working electrode at varying scan rates in aqueous 1.0M NaNO₃. Platinum mesh and Ag/AgCl counter and references electrodes made up a conventional three-electrode cell. Data from these voltammograms at 0.2V were used to calculate the specific capacitance values in the paper.

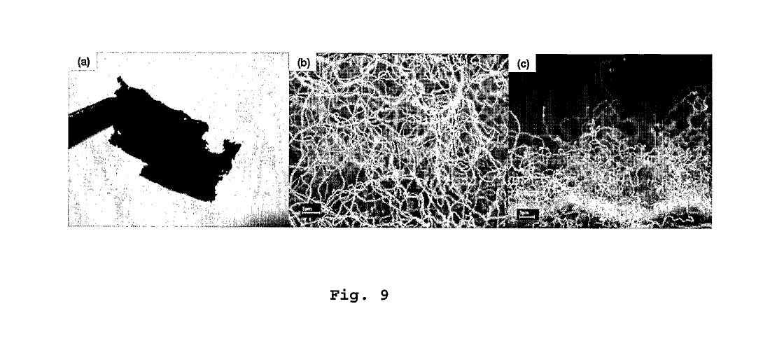

FIG. 9. Digital and SEM images of free-standing CNT/AC/metal papers, (a) digital image of CNT/AC on aluminium foil, (b) SEM image of CNT layer on aluminium foil, and (c) cross section SEM image of CNT/AC/aluminium paper.

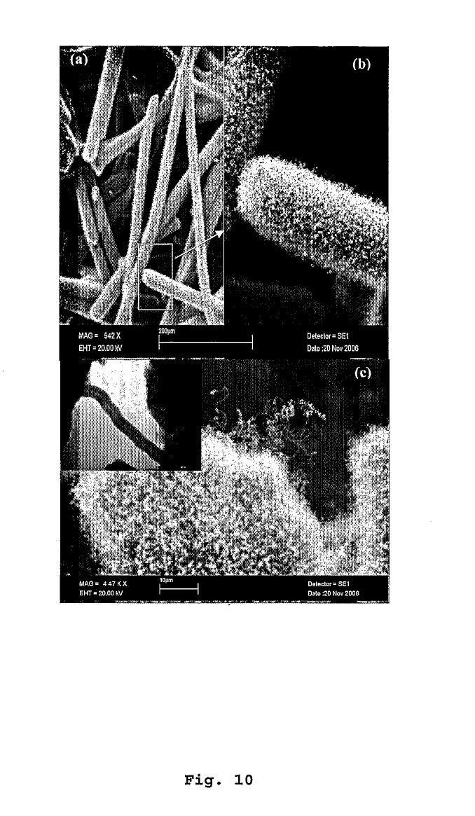

FIG. 10. Scanning Electron Micrograph (SEM) images of CNT modified carbon fiber paper, showing a dense entanglement of carbon nanotubes which entirely covers the individual carbon fibers whilst still retaining the microporous nature of the host carbon fiber paper; (b) higher resolution image of the carbon fibre indicated in (a); inset (c) Transmission Electron Microscopy (TEM) image of an individual multi-wall carbon nanotube grown on the CFP.

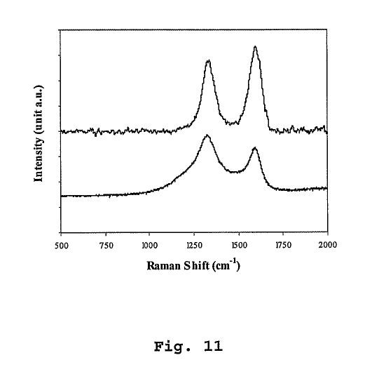

FIG. 11. Raman spectra of (a) blank carbon fiber paper and (b) CNTs modified carbon fiber paper, using 632.8 nm diode laser excitation on 900 lines/mm grating at room temperature.

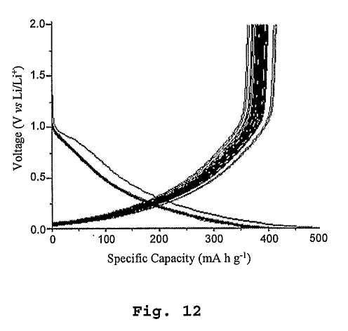

FIG. 12. The first to fiftieth charge/discharge profiles of the CNT/CFP electrode when working as the anode material in a commercial CR2032 coin cell. The current density was 0.05 mA cm⁻²

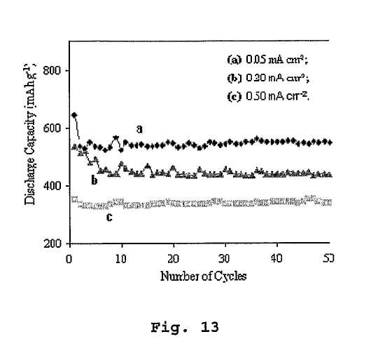

FIG. 13. Discharge capacity vs. cycle number for CNTs deposited on /CFP at different charge/discharge rate; (a) 0.05 mA cm⁻², (b) 0.20 mA cm⁻², and (c) 0.50 mA cm⁻².

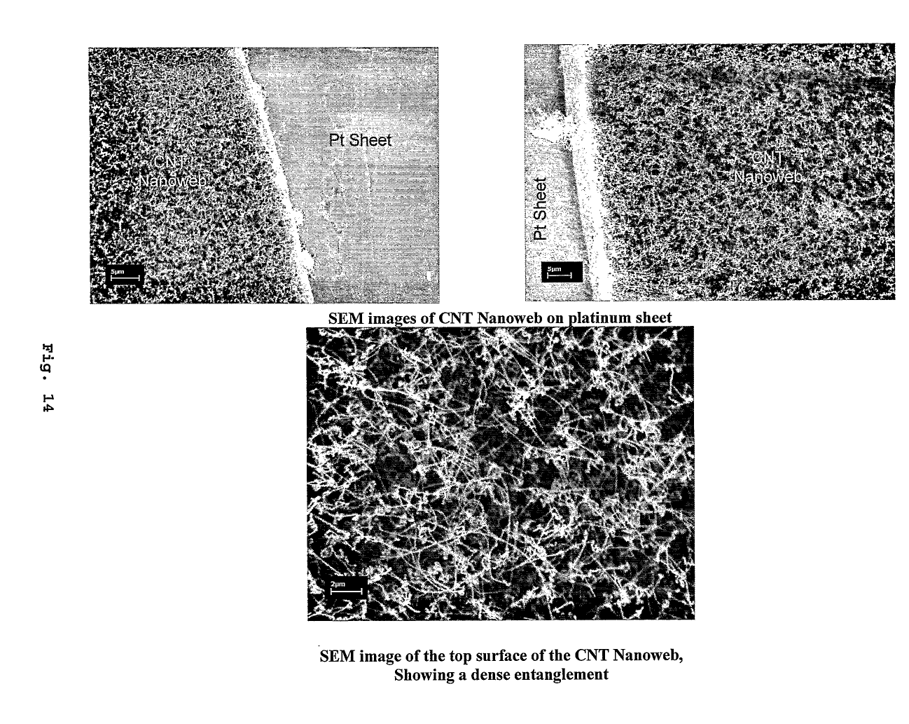

FIG. 14. SEM images of CNT nanoweb deposited on a platinum sheet.

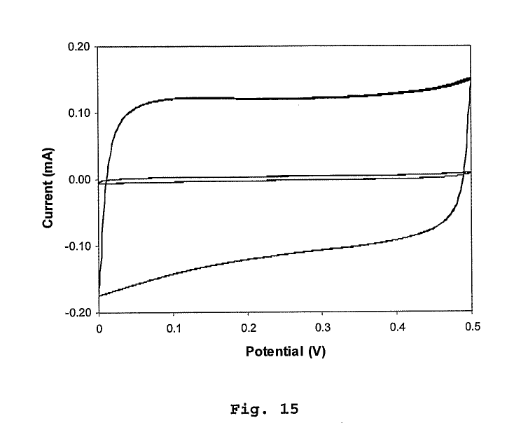

FIG. 15. Overlay of Cyclic voltammograms obtained using (a) a CNT nanoweb and (b) pure platinum sheet as the working electrode in perilymph solution at the scan rate of 100 mV s⁻¹. Data form these voltammograms are used to compare the electroactivity of CNT nanoweb with Pt sheet in bioenvironment.

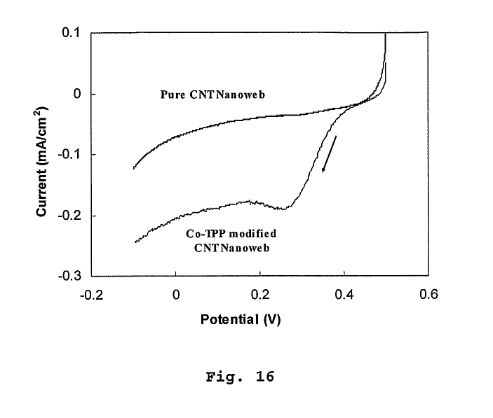

FIG. 16. Overlay of Linear sweep voltammograms (vs. Ag/AgCl) for oxygen reduction at PPy/Co-TPP modified CNT Nanoweb electrode in 0.5 M H₂SO₄ aqueous solution (under O₂ atmosphere). Scan rate: 10 mV s⁻¹. The CNT Nanoweb is modified by Co-incorporated porphyrin (oxygen reduction catalyst) containing polypyrrole film for electrocatalytic oxygen reduction reaction.

### EXAMPLES

The invention will now be described with reference to the following non-limiting example.

### Instrumentation:

SEM images were acquired using a Hitachi S-900 field-emission scanning electron microscope (FESEM). Samples for FESEM were sputter coated with chromium prior to analysis.

Raman spectroscopy measurements were performed using a Jogin Yvon Horiba HR800 Spectrometer equipped with a He:Ne laser (λ=632.8 nm) utilizing a 1800-line grating.

Electrical conductivity measurements were carried out using the conventional four-point probe method at room temperature (Jandel Engineering).

The conductivity measurements reported were the averages of 5 samples. Electrochemical experiments were performed in a standard three-electrode system, using the CNT/AC paper as working electrode, platinum mesh and Ag/AgCl as counter and reference electrodes respectively, in 0.01 M K₄Fe(CN)₆/0.1M NaNo₃, using an eDAQ e-corder (401) and potentiostat/galvanostat (EA160) with Chart v5.1.2/EChem v 2.0.2 software (AD Instruments).

Specific capacitance was calculated from the slope of anodic current amplitude @ 0.2V when graphed against the scan rate, obtained from cyclic voltammetry at different potential scan rates, in 1.0M NaNO₃ with Ag/AGCl reference electrode.

Mechanical testing was carried out using a Dynamic Mechanical analyzer Q800 (TA Instruments). The Fe content of the AC layer was measured using Energy Dispersive X-Ray Analysis (EDXA) with a Hitachi S 3000N scanning electron microscope. X-Ray Diffraction (XRD) spectra were obtained using a Philips PW1730 diffractometer with Cu Kα radiation and graphite monochrometer.

### Example

A 1 μm thin film of the catalyst (Fe(III)/TS/DBS or /PS were spin coated onto a quartz plate (3 mm thick, 4×10 cm) using a commercial spin coater (Laurell Tech) at a speed of 1000 rpm from a 10% (w/w) Fe(III)TS/ethanol solution. The catalyst film was then annealed in a conventional oven at 60-80° C. for up to 5 min until the film colour changed to a darker yellow, indicating that the ethanol solvent had evaporated.

Chemical Vapour Deposition was carried out using a commercially available Thermal CVD System (Atomate) allowing software control over gas flow, furnace temperature and deposition time. The system was flushed with argon (Ar, 150 ml/min) for 30 min, then the temperature of the furnace was increased under a gas flow of Ar (200 ml/min) and H₂ (20 ml/min), until it reached 500° C. The furnace temperature was then held at 500° C. for 10 min, which reduces the iron(III) to iron nanoparticles. The temperature was increased again, up to 800° C., whereupon acetylene (C₂H₂) was introduced for 30 min, at the gas flow rates of Ar (200 ml/min), C₂H₂ (10 ml/min) and H₂ (3 ml/min) for the growth of the carbon nanotube films. Finally, the acetylene and hydrogen gases were turned off, while the Ar (150 ml/min) was continuously flushed through the furnace until the temperature was less than 100° C. The product was cooled to room temperature, over 2 h. Faster cooling results in defects in the CNT structure.

### Results:

The resultant CNT films mode from the catalyst Fe(III)/TS (FIG. 1a), were observed to be vastly different to those grown under conventional conditions. It was apparent that during CNT growth, a very reflective layer was formed beneath the carbon film (FIG. 1b). The resultant carbon nanotube/amorphous carbon (CNT/AC) paper appeared on the quartz plate as a matt-black layer above (FIG. 1a) a flexible and shiny AC layer underneath (FIG. 1b). the CNT/AC paper could easily be removed from the substrate and this free-standing film could be rolled around a glass rod without visible signs of degradation (FIG. 1c).

Various methods were employed to characterize the CNT/AC paper. Scanning electron microscopy (SEM) revealed that the top layer (FIG. 1d) was indeed CNT, whilst the SEM image of the cross-sectional area (FIG. 1e) showed a highly porous 3-D structured CNT network grown on top of a dense amorphous carbon (AC) layer underneath (less than 1 μm thickness). The SEM image of the AC layer (FIG. 1f) displayed a uniformly dense continuous film with nano-sized porosity. The nanotubes in the CNT forest are multi-wall carbon nanotubes (MWNT) of an average length>100 μm and an external diameter of 20-40 nm. Raman spectra (see Methods) of this nanotube layer produced D and G-bands within the accepted range for MWNT samples, and XRD spectra (FIG. 6) showed the AC layer to be disordered but activated amorphous carbon. The latter spectra showed peaks in the 20 degree regions of 25 and 42 degrees, identical to those of a Commercial Carbon Black. The resistance was measured using a standard 4-probe system, with the CNT/AC paper recording a very low electronic sheet resistance of 46Ω per square, with an AC layer thickness of ˜1 μm. this resistance value is significantly lower than that of amorphous carbon (>1 kΩ per square) which is often formed during normal CVD growth of CNT forests using inorganic iron(III) compounds. The Fe content of the AC layer was measured to be <5% (value obtained from Energy Dispersive X-Ray analysis). At such a small concentration, the Fe content alone could not be considered to be responsible for the high conductivity of the AC layer.

An important aspect of this process lies in the catalyst selection. It is believed that the organic moiety in the iron(III) tosylate catalyst used here plays a key role in the formation of the highly conductive AC layer underneath the CNT upper layer. In a control experiment, to rule out any systematic issues within the CVD system, the organic catalyst was replaced with a conventional catalyst, FeCl₃. Substrates and growth parameters remained unaltered. The resultant material was typical of conventially as-grown CNT forests, where the CNT were in direct contact with the quartz substrate and covered by an insulating layer of amorphous carbon (measured to have sheet restance of 1-5 kΩ per square). The reflective layer was absent.

Two other organic ferric salts, iron(III)-dodecylbenzenesulfonate and iron(III)-pyridinesulfonate were investigated to more clearly delineate the role the organic moiety played in the formation process. CNT/AC papers were successfully synthesized on quartz plates from both these catalysts (FIGS. 7a and b). The sheet resistance of the resulting AC layer were found to be 86Ω, and 65Ω per square for the Fe(III)DBS and Fe(III)PS respectively. These resistances are similar to, but slightly higher than that of the initial CNT/AC paper grown from Fe(III)pTS (46Ω). The use of different catalysts significantly influenced CNT growth, resulting in vastly different nanotube lengths and diameters, and markedly different porosity for the resultant CNTs that comprise the 3D entangled network. FIG. 2 shows that CNT grown from Fe(III)DBS (FIG. 7a) have shorter but larger diameters nanotubes when compared with those grown from Fe(III)PS (FIG. 7b) and Fe(III)pTS (FIG. 7c). The trend D_{DBS}>D_{PS}>D_{pTS} (D=diameter) and L_{DBS}<L_{PS}, L_{pTS} (L=length), may be attributed to the different properties of Fe(III) the organic moieties. Visually, what appears to be the highest quality CNT with the greatest porosity forest were grown from Fe(III)pTS.

While these results suggest that the organic component of the catalyst material is the most likely reason for the formation of the AC layer, further experiments proved that it was not entirely responsible. The acetylene carbon source was removed from the growth process, in an attempt to isolate the reflective AC layer. To the naked eye, although glassy and/or metallic in appearance, the reflectance of the film was not as great. Electronically, the restance of this intermediate layer was found to be approximately 5kΩ. As highlighted above, the addition of the acetylene to the process and therefore the growth of the nanotubes, lowers to the AC layer resistance by the factor of >100. After re-introduction of acetylene the AC layer begins to develop the characteristics of the intergrated CNT/AC paper, confirming that both acetylene and an organic catalyst are integral to creating the superior electrode material. It is anticipated that barrier effects that plague conventional composite materials are overcome in this instance as there is intimate connection between two carbon layers (see FIGS. 2a and 2b). This also explains the extremely low resistance values measured along, and more importantly, through the CNT/AC paper.

It would be expected that a structure as the CNT/AC paper would have impressive electrochemical performance, and further characterization supports this. Cyclic voltammogrames (CV) showed a very stable, high electrochemical activity (iₚ=˜0.5 A/g) at very low scan rates (5 mV s⁻¹), highlighting the extrodanary current carrying capacity of the CNT/AC paper (FIG. 3). Recorded as Amps/g for clarity, these results were compared with the electroactivity of a commercially available multi-wall carbon nanotube mat (NanoLab, USA) as the working electrode (FIG. 3, insert). The commercial multi-wall mats iₚ value was ˜10× smaller along with a broader peak separation (ΔEₚ). These figures show that the CNT/AC paper has a much higher (5×) electroactive surface area (˜48 m²/g) and much lower electronic resistance (smaller ΔEₚ) compared to the commercial multi-wall CNT paper. Emphasising these disparities further, cyclic voltammogrames were recorded (at different scan rates (FIG. 8) in 1.0M NaNO₃) to obtain a measure of specific capacitance. The CNT/AC electrode material was calculated to have a value of 143 F/g, compared with literature values of 102 F/g reported by others for activated MWNT electrodes⁶ and 180 F/g for SWNT composites⁷. Of note is that the calculation of the capacitance and peak current values are underestimated, due to the fact that the weight of the dense AC layer is taken into account. This suggests that the true values for the nanotube layer itself should be considerably higher.

It is expected that the high surface area CNT electrodes produced using this process will have significant impact in areas involving in charge storage and/or transfer. Metal electrodes are of considerable commercial interest to the energy storage industry; copper foils for rechargeable batteries and aluminium for the capacitors. It is believed that this is the first time where highly conducting all-carbon assemblies have been directly grown on copper (FIG. 4) and aluminium (FIG. 9) foils without further modification. The Same growth parameters are employed for this new substrate and from the optical and SEM images shown a CNT/AC/metal composite material is observed. Reppeating the experiments using spin-coated inorganic FeCl₃ failed to produce stable thin films, and therefore nanotube growth, reinforcing the point that the organic nature of the Fe(III)TS is vital in this process. Similar CNT structures were deposited when glassy carbon was used as the substrate.

To further illustrate the excellent electrochemical performance of these new electrode structures, they were utilised as the anode in a Li-ion battery. In a typical experiment, a piece of carbon fiber paper (4×5 cm²) was uniformly coated with a thin iron(III)-TS film. The CVD process was initially carried out at 500° C. under Ar/H₂ gas flow to reduce the iron(III) catalyst to iron nanoparticles. The growth phase followed and was carried out at 800° C. with C₂H₂ as the carbon source. The resultant CNT growth (FIG. 10) was observed to be significantly different to those grown using conventional iron catalysts, Fe₃O₄. Scanning electron microscopy (SEM) (FIG. 10a-c) revealed the growth of a CNT layer on top of the CFP support. Transmission electron microscopy (TEM) (insert) confirmed that the layer was indeed composed of multi-wall carbon nanotubes, approximately 30-40 nm in diameter. Raman spectroscopy (FIG. 11) also confirmed that the deposited layer was indeed a well graphitized carbon nanotube layer, with D and G-bands at 1329 cm⁻¹ and 1591 cm⁻¹ respectively FIG. 10b indicates that a dense entanglement of CNTs have entirely covered the individual carbon fibers (FIG. 11) whilst still maintaining the overall porous microstructure of the carbon fiber paper. The SEM image of the root/tip area of the fiber (FIG. 10c) highlights the extremely porous nature of the CNT network. This suggests that the deposited carbon nanotubes on each carbon fiber are all highly accessible during the electrochemical cycling process, significantly increasing the electroactive surface area, which is a key parameter for electrochemical devices.

The tangled CNT/CFP composites are mechanically robust, without any visual signs of degradation, suggesting that the underlying carbon layer (formed during the CNT growth process) is strongly adhered to the carbon fiber network. The resulting CNT modified CFP can then be directly used as an electrode material in assembling electrochemical devices without further treatment. Alternatively, the modified CFP could also be used as a template for further chemical modification.

Using methods described previously⁸, a 1 cm² CNT/CFP electrode was assembled into a rechargeable Li-ion coin cell in an argon-filled glove box (Mbraum, Unilab, Germany) for battery testing (Neware, Electronic Co.) using 1.0 M LiPF₆ in ethylene carbonate/dimethyl carbonate (50:50) (Merch KgaA, Germany) as the electrolyte. The cell was cycled at room temperature between 0.01V and 2.00V under different constant charge/discharge current densities (0.05, 0.10, 0.20, and 0.50 mA cm⁻²) for the time required to reach the potential limit.

FIG. 12 shows the first to fiftieth charge/discharge curves (under constant current density 0.05 mA cm⁻²), highlighting the extremely stable electrochemical performance for the modified CNT/CFP electrode. The shape of the curves are similar to those observed previously from carbon nanotube materials, including both SWNT and MWNT 9. The electrochemical stability of these charge-discharge curves indicates a highly reversible insertion/extraction process of lithium ions into/from the carbon nanotube structure due to the unique nanostructured, high surface area CNT/CFP electrode. Coupled with mechanical and electrochemical robustness and the inherent flexibility of the material, these results highlight possible applications in a range of technological areas, not limited to Lithium-ion batteries.

The reversible capacities as a function of the cycle number are shown in FIG. 13, demonstrating the viability of the CNT/CFP as an anode material. The initial reversible capacity is as high as 643 mAh g⁻¹ under the constant discharge rate of 0.05 mA cm⁻². The electrochemical performance of the CNT/CFP electrode displayed an inherent long-term cycling stability, which is in stark contrast to the decrease in discharge capacity normally observed during the cycling of CNT-based electrodes¹⁰. After 50 cycles, the CNT/CFP electrode still demonstrated a significant, fully reversible capacity of 546 mAh g⁻¹ (FIG. 3a), which is much higher than the theoretical capacity of graphite (372 mAh g⁻¹) when used as an anode 11. This high reversible capacity obtained for our CNTs deposited on CFP electrode is attributed to its novel extremely stable and porous 3D-nanostructure. After cycling it was observed that there was no visible degradation to the electrode and no visible color change of the electrolyte over 50 cycles. It is assumed that the super-accessible surface area permits large concentrations of lithium ion insertion and extraction to occur during cycling. This result is in stark contrast to the values obtained from other CNT-based electrode structures¹².

Preliminary studies on applying different charge/discharge rates (FIGS. 13b & 13C) were carried out to investigate their abilities under high power performance. Whilst the charge/discharge capacity values are lower than those recorded at low current densities, the observed results still show a high reversible capacity of 338 mAh g⁻¹ based on CNT nets, when increasing the charge/discharge rate up to ten times from 0.05 mA cm⁻² to 0.5 mA cm⁻². This suggests that this kind of CNT/CFP electrode also has potential in the application of high power battery devices as on anode materials.

It is expected that high surface area CNT electrodes produced using this new process will have significant impact in areas involving charge storage and/or transfer. Metal electrodes are of considerable commercial interest to the energy storage industry, e.g., copper foils for rechargeable batteries and aluminum for capacitors. The versatility of the process is demonstrated in FIG. 4 where it is shown that CNT/CL composite (using the growth parameters described previously) is produced directed on copper as well as other conductive and nonconductive substrates without further modification. In the optical and SEM images shown in FIG. 4, a CNT/CL/Cu composite material is observed. In FIG. 4a, the catalyst was only coated on half of the substrate to clearly show the underlying substrate. Repeating the experiments using spin-coated inorganic FeCl₃ failed to produce stable thin films and therefore nanotube growth, reinforcing the argument that the organic nature of the Fe(III)pTS is important in this process. The contact resistance between the CL layer and the copper foil is approximately 1.0 to 2.0Ω and the resistance between the CNT web and the copper foil is in the same range.

A major advantage of this new process is that it can produce 3D structured CNT/CL networks on any substrate providing two conditions are met: i) the substrate is capable of withstanding the growth temperature of the furnace (>600° C.); and ii) the organic catalyst forms a stable thin film. These novel CNT substrates could be directly used to make electronic devices without further treatment, or to form conductive and flexible templates for further modification.

A major advantage of this process is that it can produce these CNT/AC films on any substrate providing two conditions are met: (i) the substrate is capable of withstanding the growth temperature of the furnace (>600° C.); and (ii), that the organic catalyst (Fe(III)TS) forms a stable thin film. These CNT modified metal foils, which are only a few μm thick, could be directly used to make electronic devices without further treatment, or form conductive and flexible templates for further modification.

The process for preparing these high-surface area CNT electrodes is simple, cost effective, and easy to scale. The CNT electrodes are expected to find use as flexible, thin supercapacitors and as anode materials for Li-ion rechargeable batteries and also in areas that require nanostructured electrodes for interfacing to biological systems in the pursuit of more effective nanobionic technologies.

It will be understood to persons skilled in the art of the invention that many modifications may be made without departing from the spirit and scope of the invention.

In the claims which follow and in the preceding description of the invention, except where the context requires otherwise due to express language or necessary application, the word “comprise” or variations such as “comprises” or “comprising” is used in an inclusive sense, i.e. to specify the presence of the stated features but not to preclude the presence or addition of further features in various embodiments of the invention.

### REFERENCES

1. Li, W., Xie, S., Qian, L., Chang, B., Large scale synthesis of aligned carbon nanotubes, Science, 274, 1701-1703 (1996).
2. T. Kyotani, L. Tsai, A. Tomita, Chemistry of Materials 8 (1996) 2109.
3. G. Che, B B. Lakshmi, C R. Martin, E R. Fisher, R S. Ruoff, Chemistry of Materials 10 (1999) 260
4. Yu, X., Kim, S N., Papadimitrakopoulos, F., Rusling, J F., Protein immunosensor using single-walled carbon nanotube forests with electrochemical detection of enzyme labels, Mol. Biosys. 1, 70-78 (2005).
5. Wei, C., Dai, L M., Roy, A., Benson Tolle, T., Multifunctional chemical vapour sensors of aligned carbon nanotube and polymer composites, J. Am. Chem. Soc. 128, 1412-1413 (2006).
6. Niu, C., Sichek, E K., Hoch, R., Moy, D., Tennet, H., High power electrochemical capacitors based on nanostructured carbon electrodes grown by cluster-beam deposition, Appl. Phys. Lett 70, 1480-1482 (1997).
7. Baughman, R H., Zakhidov, A., de Heer, W., Carbon Nanotubes—the Route Toward Applications, Science 297, 787-792 (2002).
8. Chen J.; Wang J.; Wang C.; Too C. O.; Wallace G. G. J. Power Sources 2006, 159, 708.
9. Frackowiak E.; Beguin F. Carbon 2002, 40, 1775.
10. Ng S. H.; Wang J.; Guo Z. P.; Chen J.; Wang G. X.; Liu H. K. Electrochimica Acta. 2005, 51, 23.
11. Shim J.; Striebel K. A.; Journal of Power Sources 2004, 130, 247.
12. Talapatra S.; Kar S.; Pal S. K.; Vajtai R.; Ci L.; Victor P.; Shaijumon M. M.; Kaur S.; Nalamasu O.; Ajayan P. M. Nature Nanotechnology 2006, 1, 112.

1. A process for preparing a nanostructured composite or a nanostructured composite substrate structure which comprises the steps of:
i) depositing an organic metal catalyst in which the organic moiety is selected from optionally substituted aryl or heteroaryl sulfonates or carboxylic acid salts on a substrate;
ii) chemical vapour deposition (CVD) growth of a nanotube network with a carbon layer underneath from the catalyst on the substrate to form a nanostructured composite substrate structure; and
iii) optionally separating the nanostructured composite from the substrate.

2. A process of claim 1 in which the organic moiety is selected from toluenesulfonates, alkylbenzene sulfonates, pyridinesulphonates, acetate or acetylacetonates.

3. A process of claim 1 in which the metal of the organic metal catalyst is selected from palladium, iron, rhodium, nickel, molybdenum and cobalt.

4. A process of claim 1 in which the organic metal catalyst is iron (III) p-toluenesulfonate (Fe(III)pTS), iron (III) dodecylbenzenesulfonate (Fe(III)DBS), iron (III) pyridinesulfonate (Fe(III)PS) iron (III) camphor sulfonic acid, nickel (II) acetate nickel (II) acetylacetonate, cobalt (II) acetate or cobalt (II) acetylacetonate.

5. A process of claim 4, in which the organic metal catalyst is iron (III) p-toluenesulfonate (Fe(III)pTS), iron (III) dodecylbenzenesulfonate (Fe(III)DBS), iron (III) pyridinesulfonate (Fe(III)PS) or iron (III) camphor sulfonic acid.

6. A process of claim 5 in which the organic metal catalyst is iron (III) p-toluenesulfonate (Fe(III)pTS).

7. A process of claim 1 in which the CVD growth involves the use of a carbon source.

8. A nanostructured composite or nanostructured composite substrate structure prepared by the process of claim 1.

9. A nanostructured composite comprising a nanotube network integrated within a carbon layer such that the growth point of the nanotubes are embedded in the carbon layer and the remaining portion of the nanotubes protrude from the carbon layer.

10. A nanostructured composite of claim 9, wherein the nanotubes are grown from metal nanoparticles that are formed by the reduction of an organic metal catalyst embedded in the carbon layer to form an intimate connection between the nanotubes and the carbon layer.

11. A composite of claim 9 which is biocompatible.

12. A composite of claim 9 in which the nanotube is an unaligned nanotube capable of forming a three-dimensional entangled network.

13. A composite of claim 12 in which the nanotube is an unaligned multi-walled nanotube.

14. A composite of claim 9 in which the nanotube is a carbon nanotube.

15. A composite of claim 9 in which the carbon layer is an activated carbon layer (CL).

16. A composite of claim 9 in which the nanotube network and/or carbon layer is attached to a substrate thereby providing a nanostructured composite substrate structure.

17. A composite of claim 16 in which the substrate is conducting or non-conducting.

18. A composite of claim 17 in which the substrate is a metal or polymeric material.

19. A composite of claim 9 in which the nanotubes, carbon layer and/or substrate is chemically modified.

20. A composite of claim 19 in which the chemical modification involves attaching biomolecules, catalysts and/or additional conductors.

21. A composite of claim 9 in which a reflective layer is formed underneath the carbon layer.

22. An article comprised wholly or partly of the nanostructured composite defined in claim 9.

23. An article of claim 22 which is electrically conducting.

24. An article of claim 23 which is selected from electrodes for energy storage and conversion; electrodes for use as fuel cells, gas storage mediums and sensors; electrodes for use in the biomedical, environmental and industrial sectors; electrodes for electrochemical deionisation; bioreactors; platforms or scaffolds for cell culturing or tissue engineering; and chemical and gas separators.
